(19) United States
(12) Patent Application Publication
(10) Pub. No.: US 2010/0148172 A1
(43) Pub. Date: Jun. 17, 2010

(54) Semiconductor device

(75) Inventors: Mitsuhisa Watanabe, Tokyo (JP); Keiyo Kusanagi, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 12/654,108

(22) Filed: Dec. 10, 2009

(30) Foreign Application Priority Data
Dec. 16, 2008 (JP) P2008-319618

(51) Int. Cl. H01L 23/544; H01L 25/065; H01L 23/52

(52) U.S. Cl. 257/48; 257/686; 257/786; 257/723; 257/690; 257/E23.141; 257/E23.179; 257/E25.013

(57) ABSTRACT

A semiconductor device includes: a semiconductor chip; a plurality of electrode pads on the semiconductor chip; a wiring board fixed to the semiconductor chip; a plurality of connection pads on the wiring board; a plurality of bonding pads aligned along two sides of the wiring board; and a plurality of leads on the wiring board. The plurality of electrode pads is in a center region of the semiconductor chip. The plurality of second connection pads faces the plurality of electrode pads. The plurality of leads connects the plurality of connection pads to the plurality of bonding pads.

### BACKGROUND OF THE INVENTION

1. Field of the Invention

The present invention relates to a semiconductor device and a method of manufacturing the same.

Priority is claimed on Japanese Patent Application No. 2008-319618, filed Dec. 16, 2008, the content of which is incorporated herein by reference.

2. Description of the Related Art

Recently, more-miniaturized and larger-capacity semiconductor devices have been proposed with miniaturization of electronic devices, such as cellular phones. Consequently, multiple semiconductor chips have to be mounted on one semiconductor device.

As a technique of mounting multiple semiconductor chips on a semiconductor device, for example, Japanese Patent Laid-Open Publication No. 2006-253175 (hereinafter, “Patent Document 1”) discloses a semiconductor device including a first semiconductor chip on a wiring board and a second semiconductor chip on the first semiconductor chip through a spacer.

As a technique of stacking, on a semiconductor device, a semiconductor chip and another semiconductor device, for example, Japanese Patent Laid-Open Publication No. 2007-516616 (hereinafter, “Patent Document 2”) discloses a semiconductor device including a semiconductor chip on a wiring board and an LGA (Land Grid Array) semiconductor device that is inverted and stacked on the semiconductor chip through a spacer.

As a technique of stacking, on a wiring board, semiconductor chips on each of which electrode pads are provided in the center region thereof, for example, Japanese Patent Laid-Open Publication No. 2005-33201 (hereinafter, “Patent Document 3”) discloses a semiconductor device including first to third semiconductor chips. The first semiconductor chip is on a wiring board. The second semiconductor chip is on the first semiconductor chip. The third semiconductor chip is on the second semiconductor chip.

Specifically, the first semiconductor chip has a center pad structure. A second wiring board is stacked on the first semiconductor chip. The second wiring board has a window in the center thereof, along which internal lands are provided. The internal lands are connected to electrode pads on the first semiconductor chip using wires passing through the window.

The internal lands are connected to external lands on the second wiring board as circuit patterns. The external lands are connected to the first wiring board using wires. The second semiconductor chip is stacked on the second wiring board through an insulating adhesive. A third wiring board is stacked on the second semiconductor chip. The third wiring board has a window along which internal lands are provided.

The electrode pads on the second semiconductor chip are connected to the internal lands on the third wiring board using wires. The internal lands on the third wiring board are connected to external lands on the third wiring board as circuit patterns in a similar manner to the second wiring board. The external lands on the third wiring board are connected to the first wiring board using wires.

However, regarding the techniques disclosed in the Patent Documents 1 and 2, it has been difficult to stack semiconductor chips each having multiple electrode pads in the center region thereof.

For example, if a semiconductor chip with electrode pads in the center region of one surface thereof is mounted on the wiring board while the other surface of the semiconductor chip facing the wiring board, wires connecting the electrode pads and the wiring board are long, thereby causing deformation of the wires, wire flowing, wire shorting, and the like.

Additionally, the wires connect the electrode pads in the center region of the semiconductor chip and the wiring board, thereby causing no space for another semiconductor chip or semiconductor device to be stacked.

Regarding the technique disclosed in Patent Document 3, the second wiring board on the first semiconductor chip has a window through which the electrode pads on the semiconductor chip and the internal lands on the second wiring board are connected using wires. Accordingly, it has been difficult to control the weight and height of the entire semiconductor device when the second semiconductor chip is stacked on the first semiconductor chip through an insulating adhesive, since excessive weight causes wire cracking, wire shorting, and the like.

Additionally, each of the second and third wiring boards has a window, causing air bubbles to be likely to remain when the semiconductor device is sealed by a seal resin, and therefore causing package cracking in a reflow process. Further, design flexibility is reduced since the formation of windows causes wire drawing.

Moreover, only the internal and external lands are provided on the second and third wiring boards, thereby making it difficult to bring a contact pin for a screening test into contact with the semiconductor chip, and therefore decreasing the manufacturing yield.

### SUMMARY

In one embodiment, a semiconductor device includes: a first wiring board having first and second regions; a plurality of first connection pads in the first region; and a first semiconductor device covering the second region. The first semiconductor device includes: a first semiconductor chip; a plurality of first electrode pads on the first semiconductor chip; a second wiring board fixed to the first semiconductor chip; a plurality of second connection pads on the second wiring board; a plurality of first bonding pads aligned along two sides of the second wiring board; and a plurality of first leads on the second wiring board. The plurality of first electrode pads is in a center region of the first semiconductor chip. The plurality of second connection pads faces the plurality of first electrode pads. The plurality of first bonding pads connects to the plurality of first connection pads. The plurality of first leads connects the plurality of second connection pads to the plurality of first bonding pads.

In another embodiment, a semiconductor device includes: a semiconductor chip; a plurality of electrode pads on the semiconductor chip; a wiring board fixed to the semiconductor chip; a plurality of connection pads on the wiring board; a plurality of bonding pads aligned along two sides of the wiring board; and a plurality of leads on the wiring board. The plurality of electrode pads is in a center region of the semiconductor chip. The plurality of second connection pads faces the plurality of electrode pads. The plurality of leads connects the plurality of connection pads to the plurality of bonding pads.

Accordingly, space above the semiconductor chip can be efficiently used since there is no need to provide wires on the wiring board fixed to the semiconductor chip thanks to the leads connecting the connection pads to the bonding pads.

Additionally, there is no land on the wiring board fixed to the semiconductor chip. Accordingly, lengths of the leads can be minimized, and widths and thicknesses of the leads can be controlled, thereby achieving a faster semiconductor device.

### BRIEF DESCRIPTION OF THE DRAWINGS

The above features and advantages of the present invention will be more apparent from the following description of certain preferred embodiments taken in conjunction with the accompanying drawings, in which:

FIGS. 1 and 2 are cross-sectional and oblique views illustrating a semiconductor device according to a first embodiment of the present invention;

FIGS. 3A to 3D are cross-sectional views indicative of a process flow illustrating a method of manufacturing a semiconductor chip on which a wiring board is mounted;

FIG. 4 is an oblique view illustrating the semiconductor chip on which the wiring board is mounted;

FIG. 5 is a cross-sectional view illustrating a screening test for the semiconductor chip on which the wiring board is mounted;

FIGS. 6A to 6D, and 7A and 7B are cross-sectional views indicative of a process flow illustrating a method of manufacturing the semiconductor device according to the first embodiment;

FIGS. 8 and 9 are oblique and cross-sectional views illustrating a semiconductor device according to a second embodiment of the present invention;

FIG. 10 is a cross-sectional view illustrating a semiconductor device according to a third embodiment of the present invention;

FIG. 11 is a cross-sectional view illustrating the semiconductor device of the first embodiment mounted on a module board;

FIG. 12 is a cross-sectional view illustrating a semiconductor device including one semiconductor chip on which a wiring board of the embodiments is provided; and

FIG. 13 is a cross-sectional view illustrating a semiconductor device including two semiconductor chips between which no wiring board of the embodiments is provided.

### DETAILED DESCRIPTION OF THE PREFERRED EMBODIMENTS

The present invention will now be described herein with reference to illustrative embodiments. The accompanying drawings explain a semiconductor device and a method of manufacturing the semiconductor device in the embodiments. The size, the thickness, and the like of each illustrated portion might be different from those of each portion of an actual semiconductor device.

Those skilled in the art will recognize that many alternative embodiments can be accomplished using the teachings of the present invention and that the present invention is not limited to the embodiments illustrated herein for explanatory purposes.

### First Embodiment

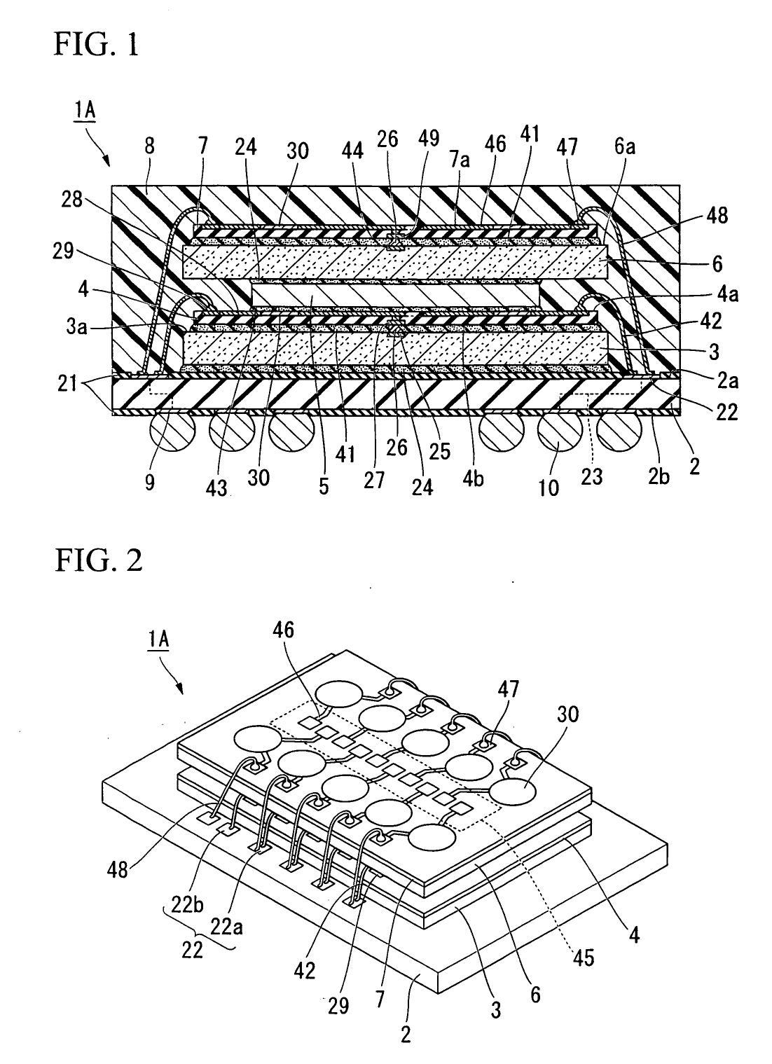

FIG. 1 is a cross-sectional view illustrating a semiconductor device 1A according to a first embodiment of the present invention. FIG. 2 is an oblique view illustrating the semiconductor device while a seal is not shown.

The semiconductor device 1A includes: a first wiring board 2; a first semiconductor chip 3 on a surface 2a of the first wiring board 2; a second wiring board 4 on the first semiconductor chip 3; a spacer 5 on the second wiring board 4; a second semiconductor chip 6 on the spacer 5; a third wiring board 7 on the second semiconductor chip 6; a seal 8 covering at least the first semiconductor chip 3, the second wiring board 4, the second semiconductor chip 6, and the third wiring board 7; lands 9 on a surface 2b of the first wiring board 2; and metal balls 10 that are external terminals on the lands 9.

The first wiring board 2 is substantially rectangular when viewed in a direction perpendicular to the surfaces 2a and 2b of the first wiring board 2, and has a predetermined thickness. The first wiring board 2 is, for example, a glass epoxy wiring board made of an insulating board, such as a glass epoxy board, in which a predetermined wiring pattern (not shown) made of Cu or the like is formed.

A solder resist film 21 that is an insulating protection film covers the surfaces 2a and 2b of the first wiring board 2 while the wiring pattern is partially uncovered by the solder resist film 21.

First connection pads 22 are provided on the wiring pattern on the surface 2a of the first wiring board 2, while the wiring pattern is uncovered by the solder resist film 21. The first connection pads 22 are aligned at a predetermined pitch along two opposing sides of the first wiring board 2. The first connection pads 22 include connection pads 22a and 22b. The connection pad 22b corresponds to an independent pin, such as a chip select terminal of the semiconductor chip as will be explained later. The connection pad 22a corresponds to a shared pin.

Lands 9 are provided on the wiring pattern on the surface 2b of the first wiring board 2, while the wiring pattern is uncovered by the solder resist film 21. The lands 9 are arranged in a grid at a predetermined pitch. The first connection pads 22 on the surface 2a and the lands 9 on the surface 2b are electrically connected using internal wires 23.

The first semiconductor chip 3 is substantially rectangular when viewed in a direction perpendicular to a surface 3a thereof. The first semiconductor chip 3 is fixed to the center of the surface 2a of the first wiring board 2 through a fixing member 24, such as an insulating adhesive or a DAF (Die Attached Film).

A predetermined circuit, such as DRAM (Dynamic Random Access Memory), is formed on the surface 3a of the first semiconductor chip 3. First electrode pads 25 are aligned in one line in the center region of the surface 3a of the first semiconductor chip 3.

The first electrode pads 25 includes ones corresponding to the independent pins, such as chip select terminals, and ones corresponding to other pins. A protection film, such as a passivation film, covers the surface 3a of the first semiconductor chip 3 while the first electrode pads 25 are uncovered by the passivation film. Wire bumps 26 made of, for example, Au are provided on the corresponding first electrode pads 25 on the center region of the first semiconductor chip 3.

The second wiring board 4 is fixed to the surface 3a of the first semiconductor chip 3 through an underfill material 41. The second wiring board 4 is substantially rectangular when viewed in a direction perpendicular to surfaces 4a and 4b thereof and has a predetermined thickness. The second wiring board 4 is, for example, a flexible wiring board made of, for example, an insulating polyamide resin, on which a predetermined wiring pattern (not shown) made of Cu or the like is formed.

The surface 4a of the second wiring board 4 has an area smaller than that of the surface 3a of the semiconductor chip 3. The second wiring board 4 is placed inside the first semiconductor chip 3 when viewed in a direction perpendicular to the surface 4a of the second wiring board 4.

Second connection pads 27 are provided on the surface 4b of the second wiring board 4 at positions corresponding to those of the first electrode pads 25 on the first semiconductor chip 3. In other words, the second connection pads 27 are aligned in one line on the center region of the surface 4b of the second wiring board 4.

First leads 28 are provided on the second wiring board 4 and extend from the center region to a side region of the surface 4a. One end of the first lead 28 electrically connects to the first connection pad 27 on the surface 4b. The other end of the first lead 28 connects to a first bonding pad 29 provided in the side region of the surface 4a.

The first bonding pads 29 are provided along two opposing sides of the second wiring board 4. Testing lands 30 are connected to the first leads 28. Insulating protection films (not shown), such as solder resist films, cover both surfaces 4a and 4b of the second wiring board 4 while the second connection pads 27, the testing lands 30, and the first bonding pads 29 are uncovered. The first electrode pads 25 on the first semiconductor chip 3 are electrically connected to the second connection pads 27 on the second wiring board 4 through the wire bumps 26.

The surface 3a of the first semiconductor chip 3 is fixed to the surface 4b of the second wiring board 4 through an insulating adhesive, such as the underfill material 41. The underfill material 41 protects the electric connection of the first electrode pads 25 and the second connection pads 27 through the wire bumps 26.

The first bonding pads 29 along the two opposing sides of the second wiring board 4 are electrically connected to the corresponding first connection pads 22 on the first wiring board 2 using conductive first wires 42 made of, for example, Au.

The spacer 5 is fixed to the center region of the surface 4a of the second wiring board 4 through an insulating adhesive 43. The second semiconductor chip 6 is fixed to the spacer 5 through a fixing member 24, such as an insulating adhesive or a DAF (Die Attached Film). For example, a Si board is used as the spacer 5, but various materials may be used as long as space for the first wires 42 is provided.

A solder resist film (not shown) covers the surface 4a of the second wiring board 4 while the testing lands 30 and the first bonding pads 29 are uncovered, and the spacer 5 is fixed to the second wiring board 4 through the insulating adhesive 43, thereby preventing the first leads 28 from shorting.

The second semiconductor chip 6 has the same structure as that of the first semiconductor chip 3. A predetermined circuit, such as DRAM, is formed on a surface 6a of the second semiconductor chip 6. Second electrode pads 44 are aligned in one line on the center region of the surface 6a.

Similar to the first semiconductor chip 3, the second electrode 44 includes electrode pads 44a and 44b (not shown). The electrode pad 44b corresponds to an independent pin, such as a chip select terminal. The electrode pad 44a corresponds to a shared pin.

A protection film (not shown), such as a passivation film, covers the surface 6a of the second semiconductor chip 6 while the second electrode pads 44 are uncovered by the passivation film.

Similar to the first semiconductor chip 3, the third wiring board 7 is fixed to the surface 6a of the second semiconductor chip 6. The third wiring board 7 has the same structure as that of the second wiring board 4. Third connection pads 49 on a surface 7b of the third wiring board 7 are electrically connected to the corresponding second electrode pads 44 on the second semiconductor chip 6 through the wire bumps 26.

Second leads 46 on the center region 45 of the surface 7a of the third wiring board 7 has the same structure as that of the first leads 28. Second bonding pads 47 along the opposing sides of the surface 7a of the third wiring board 7 are at the same positions of the first bonding pads 29 along the opposing sides of the second wiring board 4 if viewed in a direction perpendicular to the surface 7a of the third wiring board 7. Accordingly, the first and second semiconductor chips 3 and 6 have the same wiring structure.

The second bonding pads 47 on the third wiring board 7 are electrically connected to the corresponding first connection pads 22 on the first wiring board 2 using second conductive wires 48 made of, for example, Au.

The first and second semiconductor chips 3 and 6 are circuits having the same function. The wires 42 and 48 respectively correspond to the first and second electrode pads 25 and 44, which can be shared, are connected to the same first connection pads 22a. The wires 42 and 48 respectively corresponding to the first and second electrode pads 25 and 44, such as chip select terminals which cannot be shared, are connected to the different first connection pads 22b.

The seal 8 is provided on the side of the surface 2a of the first wiring board 2. The seal 8 covers at least the first semiconductor chip 3, the second wiring board 4, the second semiconductor chip 6, the third wiring board 7, the first and second wires 42 and 48. The seal 8 is made of an insulating thermosetting resin, such as an epoxy resin.

Lands 9 are provided on the surface 2b of the first wiring board 2. The metal balls 10, such as solder balls, are mounted on the corresponding lands 9. The metal balls 10 will be external terminals serving as adhesives for mounting the semiconductor device 1A onto a motherboard.

As explained above, the second wiring board 4 is fixed to the surface 3a of the first semiconductor chip 3 while the first and second electrode pads 25 and 27 are correspondingly positioned in the center regions of the first semiconductor chip 3 and the second wiring board 4, respectively. Consequently, space above the surface 3a of the first semiconductor chip 3 can be efficiently used.

In other words, the first leads 28 extend from the second connection pads 27 to side regions of the second wiring board 4. For this reason, there is no need to provide wires in the center region of the second wiring board 4. Accordingly, space above the center region of the semiconductor chip 3 can be efficiently used. Therefore, the second semiconductor chip 6 can be fixed to the second wiring board 4 through the spacer 5.

Similarly, the third wiring board 7 is fixed to the second semiconductor chip 6. Accordingly, space above the second semiconductor chip 6 can be efficiently used. Thus, multiple semiconductor chips can be stacked, thereby enabling a high-performance and high-capacity semiconductor device. For example, three or more semiconductor chips each having electrode pads in the center region thereof can be stacked.

Additionally, lands are not provided on the wiring boards 4 and 7, thereby minimizing the lengths of the leads 28 and 46. Further, the widths and the thicknesses of the leads 28 and 46 can be controlled, thereby enabling the faster semiconductor device 1A.

Moreover, the wiring boards 4 and 7 have no opening, thereby preventing the seal 8 from including air bubbles. Additionally, adhesion of the wiring boards to the seal is greater than that of the semiconductor chips to the seal, thereby increasing the reliability of the semiconductor device 1A.

Further, the testing lands 30 are connected to the leads 28 and 46, and therefore non-defective semiconductor chips after screening tests can be mounted, thereby increasing the manufacturing yield of the semiconductor device 1A.

Moreover, the bonding pads 29 and 47 are provided along the opposing sides of the wiring boards 4 and 7 fixed to the semiconductor chips 3 and 6, respectively, thereby minimizing the lengths of the wires 42 and 48, and therefore preventing the wires 42 and 48 from contacting each other, and preventing the wires 42 and 48 from contacting side edges of the semiconductor chips 3 and 6.

Since the lengths of the wires 42 and 48 are minimized, the first connection pads 22 on the first wiring board 2 can be disposed closer to the first semiconductor chip 3. Conventionally, those wires are long and slack, and connection pads had to be disposed far from the semiconductor chip to prevent the wires from contacting the semiconductor chip.

In the first embodiment, the lengths of the wires 42 and 48 can be minimized, thereby preventing the wires 42 and 48 from being slack, and enabling the first connection pads 22 to be disposed closer to the first semiconductor chip 3. Accordingly, the first wiring board 2 can be miniaturized, resulting in miniaturization of the semiconductor device 1A.

Further, the first semiconductor chip 3 and the second wiring board 4, and the second semiconductor chip 6 and the third wiring board 7 are connected by flip-chip connection, thereby making the semiconductor device 1A thinner and enhancing the electric characteristics thereof.

Moreover, the first electrode pad 25 on the first semiconductor chip 3 and the second electrode pad 44 on the second semiconductor chip 6, which can be shared, are commonly connected to the same first connection pad 22a through leads 28 and 46, and the wires 42 and 48, thereby enabling miniaturization of the semiconductor device 1A and simplification of wiring structures.

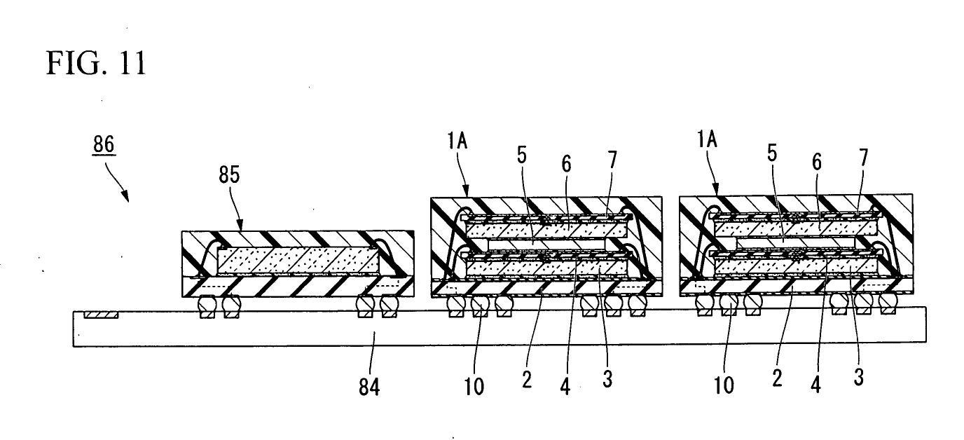

FIG. 11 is a cross-sectional view illustrating the semiconductor device 1A mounted on a module board. Multiple semiconductor devices 1A and a semiconductor control device 85 are mounted on a module board 84, thus forming a memory module 86. Miniaturization and higher-capacity of the semiconductor device 1A can be achieved in the first embodiment, thereby enabling miniaturization and higher-capacity of the memory module 86.

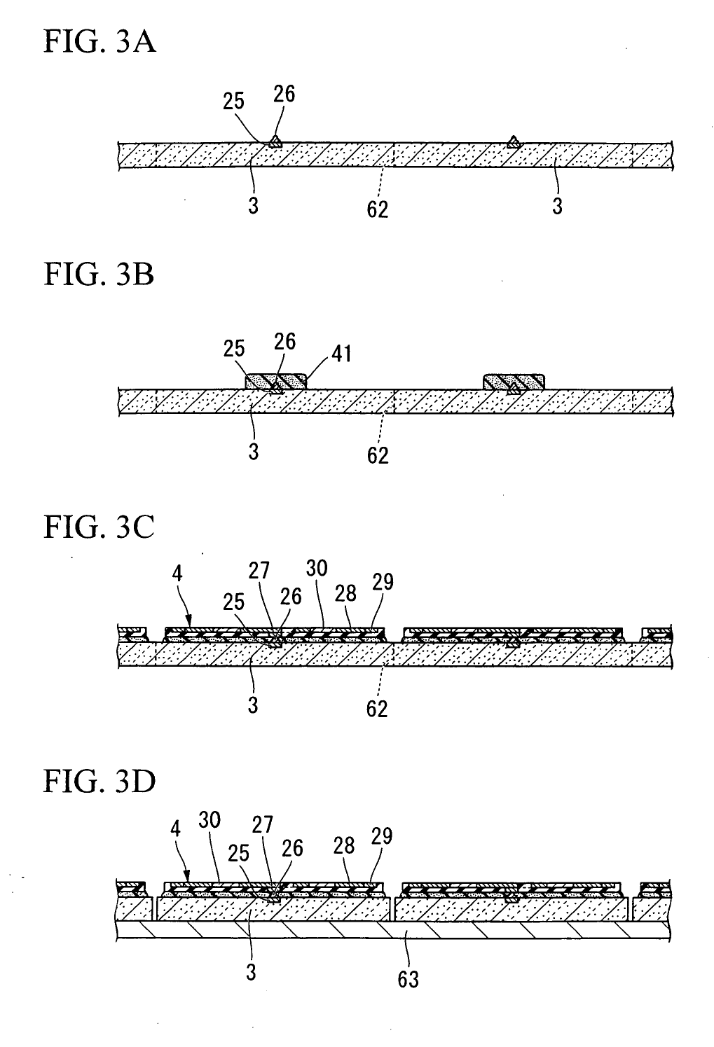

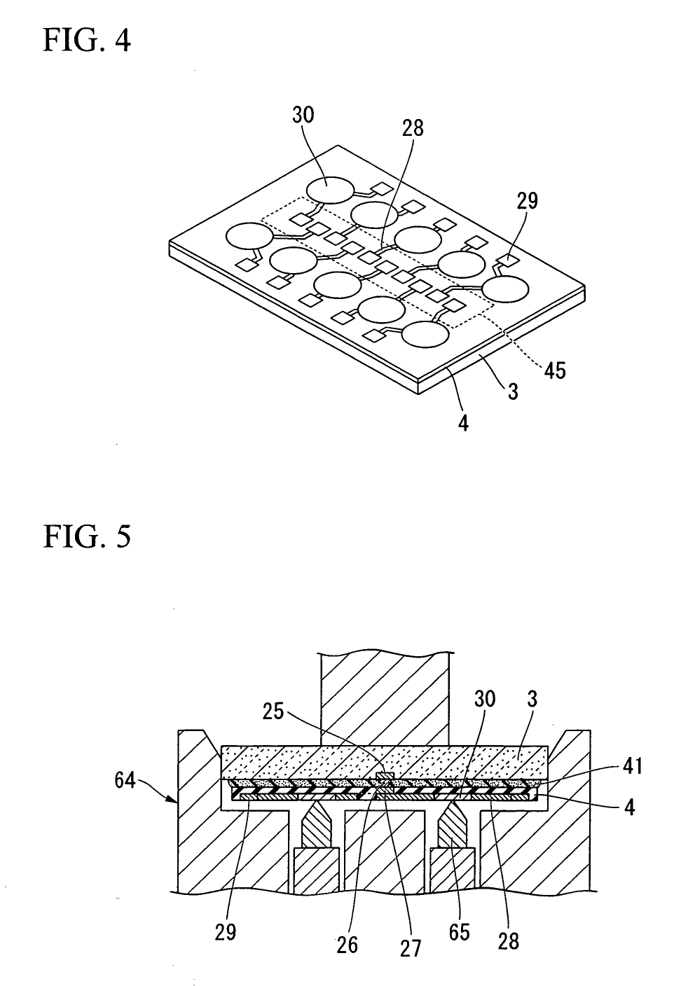

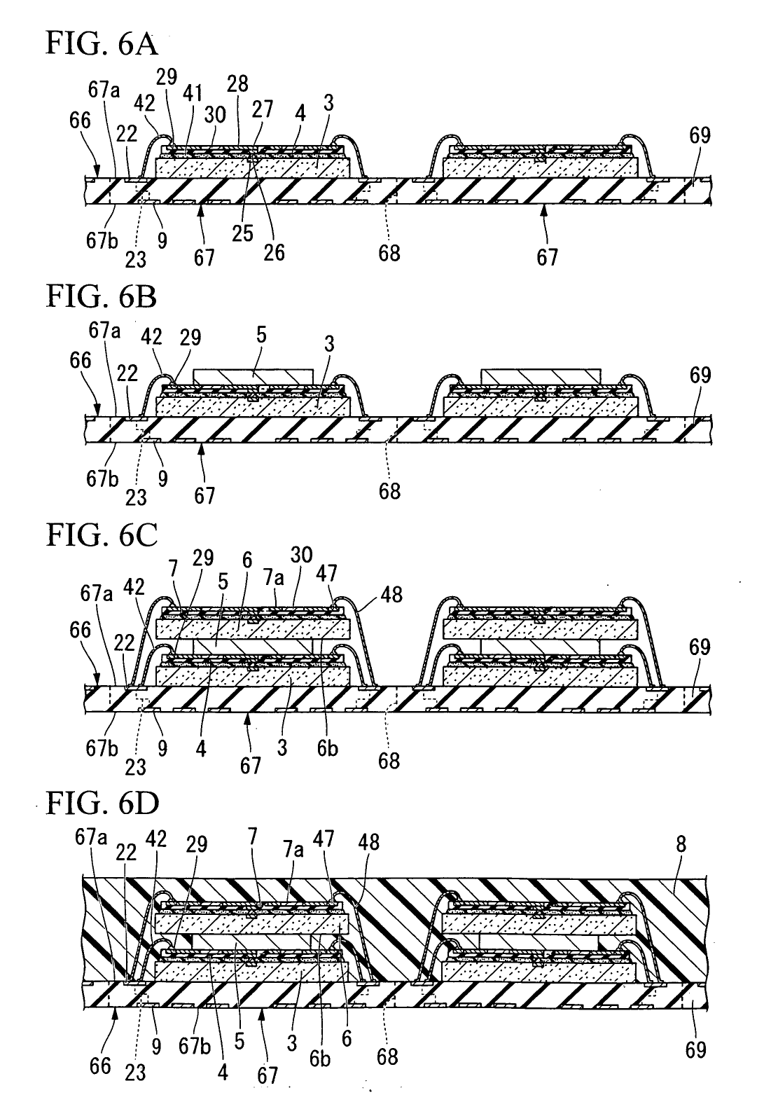

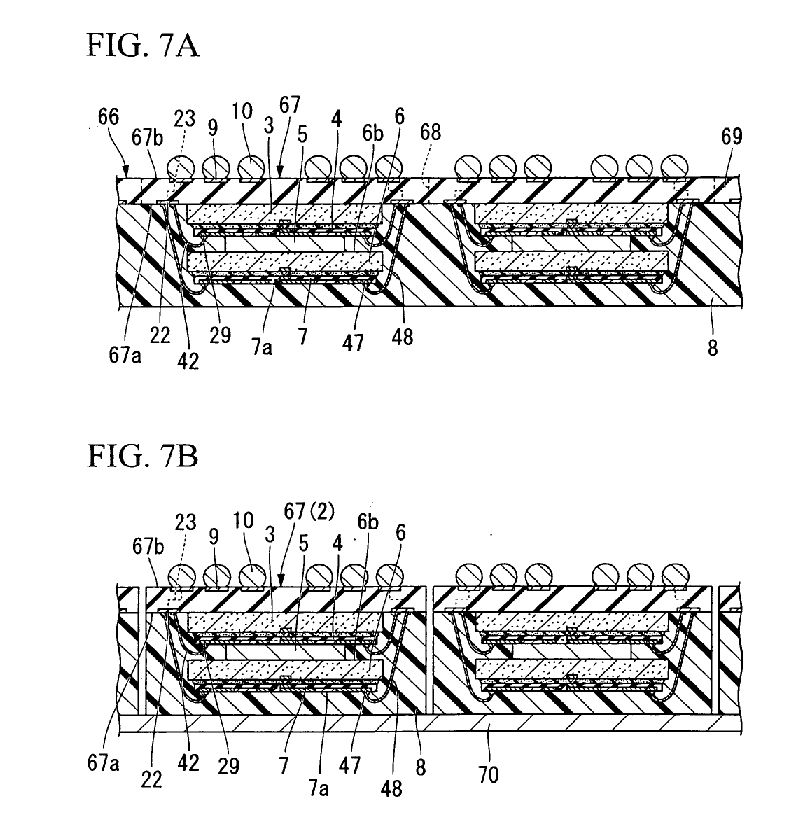

Hereinafter, a method of manufacturing the semiconductor device 1A is explained. FIGS. 3A to 3D are cross-sectional views indicative of a process flow illustrating a method of manufacturing the first semiconductor chip 3 on which the second wiring board 4 is mounted. FIG. 4 is an oblique view illustrating the semiconductor chip 3 on which the second wiring board 4 is mounted. FIG. 5 is a cross-sectional view illustrating a screening test for the first semiconductor chip 3. FIGS. 6A to 6D, and 7A and 7B are cross-sectional views indicative of a process flow illustrating a method of manufacturing the semiconductor device 1A.

Hereinafter, a method of manufacturing the first semiconductor chip 3 on which the second wiring board 4 is mounted is explained with reference to FIGS. 3A to 3D, and FIG. 4. The same method can apply to a method of manufacturing the second semiconductor chip 6 on which the third wiring board 7 is mounted, and therefore explanations thereof is omitted here.

A semiconductor wafer 61 used for manufacturing the semiconductor device 1A is formed by forming, through a diffusion process and the like, a predetermined circuit and electrode pads (not shown) on a surface of a circular substrate obtained by slicing a silicon ingot formed by a single crystal pulling method.

The boundaries among the first semiconductor chips 3 on the semiconductor wafer 61 are dicing lines 62. The first electrode pads 25 are provided in the center region of each first semiconductor chip 3.

Then, the conductive wire bumps 26 are formed on the first electrode pads 25 on the first semiconductor chip 3, as shown in FIG. 3A. Specifically, one end of a conductive wire made of, for example, Au is melted to be in a ball shape using a wire bonding apparatus (not shown). Then, the ball-shaped end is connected to the electrode pad by ultrasonic thermocompression. Then, the other end of the wire is cut. Thus, the wire bump 26 is formed.

Then, an underfill material 41 that is an insulating adhesive is provided by application onto the center region of the first semiconductor chip 3 using a mask (not shown) mounted on the semiconductor wafer 61, as shown in FIG. 3B.

Then, the second wiring board 4 is mounted on each first semiconductor chip 3, as shown in FIG. 3C. The second wiring board 4 is substantially rectangular when viewed in a direction perpendicular to the surfaces 4a and 4b thereof. For example, the second board 4 is a flexible wiring board formed by forming a predetermined wiring pattern made of Cu or the like on a surface of an insulating board made of, for example, a polyamide resin.

The second connection pads 27 are disposed on the center region of the surface 4b of the second wiring board 4 so as to face the first electrode pads 25 on the first semiconductor chip 3. The first leads 28 extending from the center region 45 to the side region are provided on the second wiring board 4, as shown in FIG. 4.

One end of the first lead 28 extends to the center region of the second wiring board 4 and connects to the connection pad 27 on the surface 4b. The other end of the first lead 28 extends to the side region of the second wiring board 4 and connects to the first bonding pad 29.

The first bonding pads 29 are disposed along the opposing sides of the second wiring board 4. The testing land 30 is connected to each of the first leads 28. Insulating protection films (now shown), such as solder resist films, cover both surfaces 4a and 4b of the second wiring board 4 while the second connection pads 27, the testing lands 30, and the first bonding pads 29 are uncovered by the insulating protection films.

The second wiring board 4 has an area smaller than that of the first semiconductor chip 3, and is distanced from the dicing line 62 by at least substantially 50 μm to 100 μm.

In other words, the second wiring board 4 is inside the first semiconductor chip 3 when viewed in a direction perpendicular to the surface 4a of the second wiring board 4. For this reason, when the second wiring boards 4 are mounted on the corresponding first semiconductor chips 3 on the semiconductor wafer 61, the adjacent second wiring boards 4 can be prevented from contacting each other, thereby enabling simple mounting of the second wiring boards 4.

Then, the second wiring board 4 is mounted on the corresponding first semiconductor chip 3 by fixing the second connection pads 27 onto the corresponding first electrode pads 25 by thermocompression using a bonding apparatus (not shown). Consequently, the underfill material 41 on the center region of the first semiconductor chip 3 spreads between the first semiconductor chip 3 and the second wiring board 4.

Then, the semiconductor wafer 61 is diced into pieces of the first semiconductor chips 3, as shown in FIG. 3D. Specifically, the semiconductor wafer 61 is held on a ring-shaped fixing member (not shown) on which a dicing tape 63 is attached, and then is cut using a rapidly-rotating dicing blade into multiple pieces of the first semiconductor chips.

In this case, the second wiring board 4 on the first semiconductor chip 3 is distanced from the dicing line 62 by 50 μm to 100 μm. For this reason, the second wiring board 4 is not in contact with the dicing blade upon dicing, thereby preventing the second wiring board 4 from peeling from the semiconductor chip 3, and therefore enabling excellent dicing.

Additionally, the underfill material 41 is not present at regions of the semiconductor wafer 61 to be diced, thereby preventing the dicing blade from being worn caused by a filler included in the underfill material 41.

After the dicing process, the dicing tape 63 is irradiated with UV (Ultraviolet) light to decrease adhesive power. Then, the semiconductor chip 3 is detached from the dicing tape 63 using a pressing unit of a picking-up apparatus (not shown). Thus, the first semiconductor chip 3 on which the second wiring board 4 is mounted as shown in FIG. 4 can be obtained.

Then, the first semiconductor chip 3 on which the second wiring board 4 is mounted is mounted on a screen testing socket 64, as shown in FIG. 5. Then, contact pins 65 of the socket 64 are electrically connected to the testing lands 30 to screen the first semiconductor chip 3. Consequently, only non-defective first semiconductor chips 3 can be obtained.

Then, a method of manufacturing the semiconductor device 1A is explained with reference to FIGS. 6A to 6D, and FIGS. 7A and 7B. As shown in FIG. 6A, a wiring motherboard 66 used for manufacturing the semiconductor device 1A is to be processed by MAP (Mold Array Process). The wiring motherboard 66 is substantially rectangular in a plane view, and multiple element formation units 67 are arranged in a grid on the wiring motherboard 66.

Each of the element formation units 67 becomes the first wiring board 2 after dicing. The wiring motherboard 66 is made of a glass epoxy board having a thickness of, for example, 0.25 mm. Wires (not shown) are provided on both surfaces of the wiring motherboard 66. Insulating films (not shown), such as solder resist films, partially cover both surfaces of the wiring motherboard 66.

The first connection pads 22 are provided on the wires on a surface 67a of the element formation unit 67 where the wires are uncovered by the solder resist film. The lands 9 are arranged in a grid on the wires on a surface 67b of the element formation unit 66 where the wires are uncovered by the solder resist film. The first connection pads 22 are electrically connected to the corresponding lands 9 using internal wires 23.

A frame 69 is provided surrounding the element formation units 67 in a grid. The frame 69 has positioning holes used for transportation and positioning at a predetermined pitch. Boundaries among the element formation units 67 are the dicing lines 68. Thus, the wiring motherboard 66 is prepared.

Then, the surface 3b of the first semiconductor chip 3 on which the second wiring board 4 shown in FIG. 4 is mounted is fixed to the center of the surface 67a of the element formation unit 67 using a die-bonding apparatus (now shown) through the fixing member 24 shown in FIG. 1, such as an insulating adhesive or a DAF.

Then, the first bonding pads 29 along the opposing sides of the surface 4a of the second wiring board 4 are electrically connected to the corresponding first connection pads 22 on the element formation unit 67 of the wiring motherboard 66 using the conductive first wires 42.

Specifically, one end of the first wire 42 made of Au or the like is melted to be in a ball-shape using a wire-bonding apparatus (now shown). Then, the ball-shaped end is connected by ultrasonic thermocompression to the first bonding pad 29 on the second wiring board 4. Then, the first wire 42 is made into a loop, and the other end of the first wire 42 is connected by ultrasonic thermocompression to the first connection pad 22 on the element formation unit 67.

Thus, all the first bonding pads 29 on the second wiring substrate 4 are connected to the corresponding first connection pads 22 on the element formation unit 67 using the first wires 42.

As explained above, the first bonding pads 29 are provided along the opposing sides of the second wiring board 4, thereby enabling the length of the first wire 42 to be minimized, and therefore preventing the wires 42 from contacting each other and preventing the wire 42 from contacting a side edge of the first semiconductor chip 3.

Further, the first connection pads 22 can be positioned closer to the first semiconductor chip 3 thanks to the first wire 42 minimized in length, thereby enabling miniaturization of the element formation unit 67.

Then, the spacer 5 is fixed to the center of the surface 4a of the second wiring board 4 through the insulating adhesive 43 shown in FIG. 1, as shown in FIG. 6B. The spacer 5 is made of, for example, a Si board. However, various materials can be used as the spacer 5 as long as space for the first wires 42 can be provided.

Then, the surface 6b of the second semiconductor chip 6 on which the third wiring board 7 is mounted is fixed to the spacer 5 through the fixing member 24, such as an insulating adhesive or a DAF, using a die-bonding apparatus (not shown), as shown in FIG. 6C. In the first embodiment, the first and second semiconductor chips 3 and 6 are semiconductor chips having the same function.

Then, similar to the second wiring board 4, the second bonding pads 47 provided along the opposing sides of the surface 7a of the third wiring board 7 are electrically connected to the corresponding connection pads 22 on the element formation unit 67 using the conductive second wires 48.

The first and second semiconductor chips 3 and 6 are circuits having the same function. The first and second wires 42 and 48 corresponding to the first and second electrode pads 25 and 44, which can be shared, are connected to the same first connection pad 22a on the element formation unit 67 shown in FIG. 2. The first and second wires 42 and 48 corresponding to the first and second electrode pads 25 and 44, which cannot be shared, are connected to the different first connection pads 22b shown in FIG. 2.

Then, the seal 8 made of an insulating resin, such as a thermosetting epoxy resin, is formed to collectively cover the element formation units 67 of the wiring motherboard 66, as shown in FIG. 6D. Specifically, the wiring motherboard 66 is fixed onto upper and lower molds of a transfer mold apparatus (not shown), and then a seal resin is provided into a cavity between the upper and lower molds. Then, the seal resin is thermally cured to be the seal 8 covering at least the first and second semiconductor chips 3 and 6, the second and third wiring boards 4 and 7, the first and second wires 42 and 48.

As explained above, the third wiring board 7 is fixed on the surface 6a of the second semiconductor chip 6, thereby increasing the adhesion to the seal 8, and therefore increasing the reliability of the semiconductor device 1A.

Then, the metal balls 10 that are external terminals are mounted on the corresponding lands 9 on the surface 67b of the element formation unit 67, as shown in FIG. 7A. For example, solder balls are used as the metal balls 10.

Specifically, the metal balls 10 are held by suction on suction holes of a mounting apparatus (not shown) while the positions of the metal balls 10 are adjusted to the positions of the lands 9. Then, the metal balls 10 are collectively mounted on the corresponding lands 9 through a flux. Then, the wiring motherboard 66 is reflowed at a predetermined temperature. Thus, the metal balls 10 are mounted on the lands 9.

Then, the wiring motherboard 66 is diced along the dicing lines 68 using a dicing apparatus (not shown) into pieces of the element formation units 67, as shown in FIG. 7B.

Specifically, the seal 8 is fixed by adhesion onto a dicing tape 70. Then, the wiring motherboard 66 is vertically and horizontally diced along the dicing lines 68 using a dicing blade (not shown) into pieces of the element formation units 67. Then, each piece is picked up from the dicing tape 70. Thus, the semiconductor device shown in FIG. 1 can be obtained.

### Second Embodiment

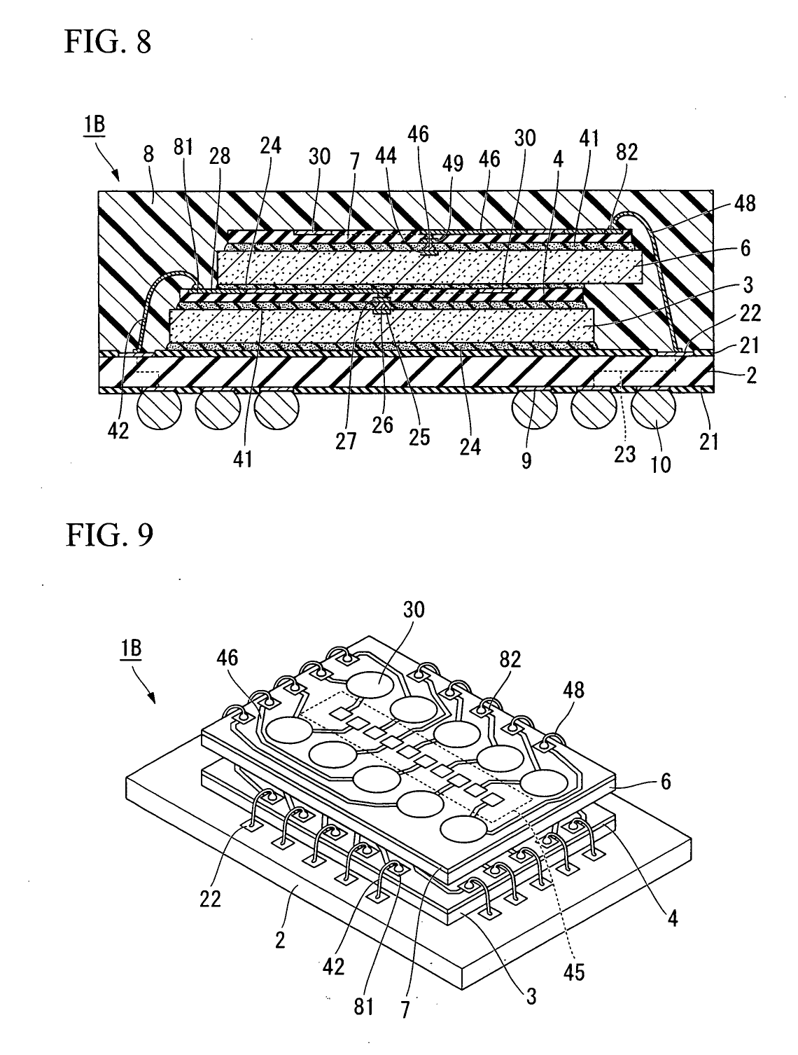

FIG. 8 is a cross-sectional view illustrating a semiconductor device 1B according to a second embodiment of the present invention. FIG. 9 is an oblique view illustrating the semiconductor device 1B.

In the second embodiment, only the arrangement of bonding pads on the second and third wiring boards 4 and 7 are changed. Therefore, explanations of the same structures as those of the first embodiment are omitted here.

In the second embodiment, first bonding pads 81 are provided along two adjacent sides of the second wiring board 4. Similarly, second bonding pads 82 are provided along two adjacent sides of the third wiring board 7.

The second semiconductor chip 6 to which the third wiring board 7 is fixed is fixed to the second wiring board 4 through the fixing member 24 without a spacer, as shown in FIGS. 8 and 9. The second semiconductor chip 6 turns 180 degrees to be fixed to the second wiring board 4. The first bonding pads 81 are positioned so as not to overlap the second semiconductor chip 6 and the third wiring board 7 when viewed in a direction perpendicular to the surface 7a of the third wiring board 7.

Consequently, the first and second bonding pads 81 and 82 are aligned along the four different sides of the second wiring board 4 and the second semiconductor chip 6, thereby achieving the same effect as that of the first embodiment. Additionally, the spacer 5 is not necessary in the second embodiment, thereby making the semiconductor device 1B thinner.

Further, there or more semiconductor chips can be stacked without a spacer or the like by providing the first and second bonding pads 81 and 82 along adjacent two sides of the wiring boards and by mounting the second semiconductor chip 6 turned by 180 degrees.

### Third Embodiment

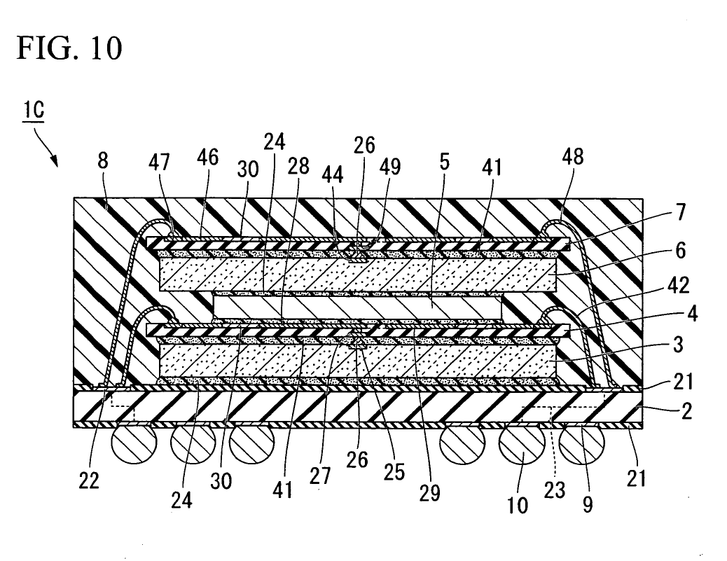

FIG. 10 is a cross-sectional view illustrating a semiconductor device 1C according to a third embodiment of the present invention. The third embodiment is a modification of the first embodiment. Therefore, explanations of the elements are omitted here.

Regarding the semiconductor device 1C shown in FIG. 10, the second wiring board 4 has an area greater than that of the first semiconductor chip 3. The semiconductor chip 3 is inside the second wiring board 4 when viewed in a direction perpendicular to the surface 4a of the second wiring board 4. The second semiconductor chip 6 and the third wiring board 7 have the same structural relationship as that of the first semiconductor chip 3 and the second wiring substrate 2.

Accordingly, the same effect as that of the first embodiment can be achieved. Additionally, the wires 42 and 48 can be prevented from contacting side edges of the semiconductor chips 3 and 6, thereby preventing the semiconductor ships 3 and 6 from cracking.

It is apparent that the present invention is not limited to the above embodiments, but may be modified and changed without departing from the scope and spirit of the invention.

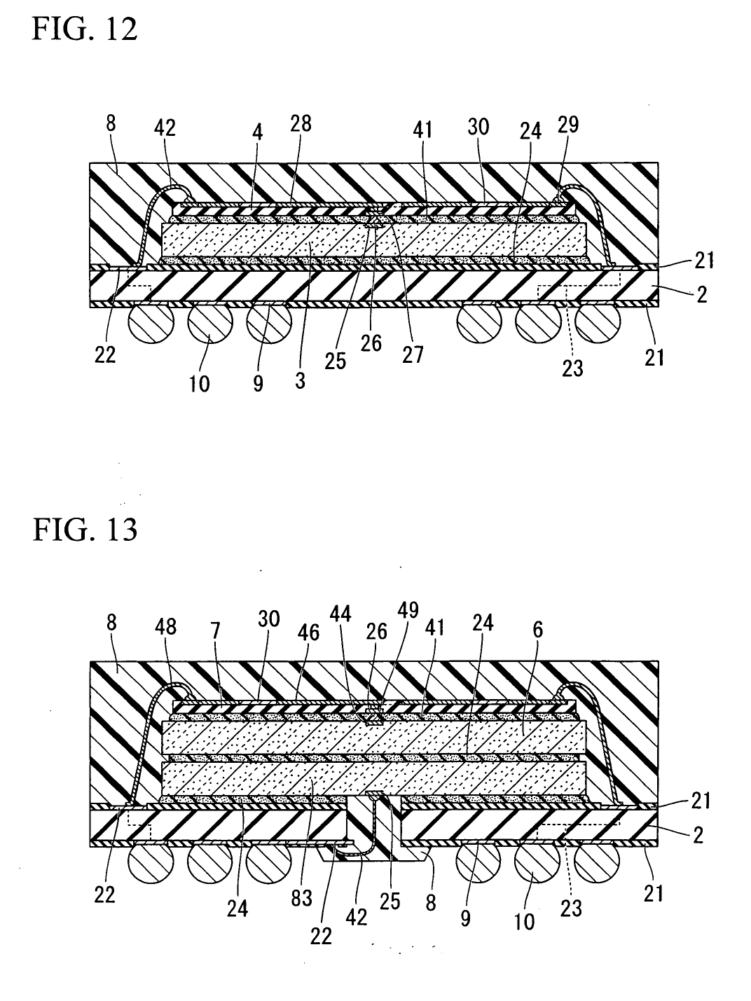

For example, although the semiconductor device including multiple stacked semiconductor chips has been taken as an example, the present invention is applicable to a single semiconductor device as shown in FIG. 12.

Additionally, although the case where multiple pairs of semiconductor chips and wiring boards are stacked has been explained, the present invention is applicable to the case where a wiring board is not stacked on each semiconductor chip, as in the case of a lower semiconductor chip 83 shown in FIG. 13.

Further, the case where a flexible wiring board is used as the wiring board to be stacked on a semiconductor chip has been explained, a glass epoxy wiring board may be used. Moreover, although the case where semiconductor chips each having the same function are stacked has been explained, different semiconductor chips may be stacked.

The present invention is widely applicable to semiconductor device manufacturing industries.

As used herein, the following directional terms “forward, rearward, above, downward, vertical, horizontal, below, and transverse” as well as any other similar directional terms refer to those directions of a device equipped with the present invention. Accordingly, these terms, as utilized to describe the present invention should be interpreted relative to a device equipped with the present invention.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

What is claimed is:

1. A semiconductor device comprising:
a first wiring board having first and second regions;
a plurality of first connection pads in the first region; and
a first semiconductor device covering the second region, the first semiconductor device comprising:
a first semiconductor chip;
a plurality of first electrode pads on the first semiconductor chip, the plurality of first electrode pads being in a center region of the first semiconductor chip;
a second wiring board fixed to the first semiconductor chip;
a plurality of second connection pads on the second wiring board, the plurality of second connection pads facing the plurality of first electrode pads;
a plurality of first bonding pads aligned along two sides of the second wiring board, the plurality of first bonding pads connecting to the plurality of first connection pads; and
a plurality of first leads on the second wiring board, the plurality of first leads connecting the plurality of second connection pads to the plurality of first bonding pads.

2. The semiconductor device according to claim 1, wherein the first semiconductor device further comprising:
a plurality of first testing lands connecting to the plurality of first leads.

3. The semiconductor device according to claim 1, wherein the plurality of first bonding pads are aligned along two opposing sides of the second wiring board.

4. The semiconductor device according to claim 1, wherein the plurality of first bonding pads are aligned along two adjacent sides of the second wiring board.

5. The semiconductor device according to claim 1, wherein the second wiring board is inside the first semiconductor chip when viewed in a direction perpendicular to facing surfaces of the first semiconductor chip and the second wiring board.

6. The semiconductor device according to claim 1, wherein the first semiconductor chip is inside the second wiring board when viewed in a direction perpendicular to facing surfaces of the first semiconductor chip and the second wiring board.

7. The semiconductor device according to claim 1, further comprising
a seal covering the first region and the first semiconductor device.

8. The semiconductor device according to claim 1, further comprising:
a second semiconductor device fixed to the first semiconductor device, the second semiconductor device comprising:
a second semiconductor chip;
a plurality of second electrode pads on the second semiconductor chip, the plurality of second electrode pads being in a center region of the second semiconductor chip;
a third wiring board fixed to the second semiconductor chip;
a plurality of third connection pads on the third wiring board, the plurality of third connection pads facing the plurality of second electrode pads;
a plurality of second bonding pads aligned along two sides of the third wiring board, the plurality of second bonding pads connecting to the plurality of first connection pads; and
a plurality of second leads on the third wiring board, the plurality of second leads connecting the plurality of third connection pads to the plurality of second bonding pads.

9. The semiconductor device according to claim 8, wherein the second semiconductor device further comprising:
a plurality of second testing lands connecting to the plurality of second leads.

10. The semiconductor device according to claim 8, further comprising:
a spacer connecting the first and second semiconductor devices.

11. The semiconductor device according to claim 10, wherein the spacer is inside the second wiring board, and the plurality of first bonding pads are outside the spacer and inside the first semiconductor chip, when viewed in a direction perpendicular to facing surfaces of the second semiconductor chip and the third wiring board.

12. The semiconductor device according to claim 8, wherein
the plurality of first bonding pads are aligned along two opposing sides of the second wiring board,
the plurality of second bonding pads are aligned along two opposing sides of the third wiring board, and
the two opposing sides of the second wiring board are parallel to the two opposing sides of the third wiring board when viewed in a direction perpendicular to facing surfaces of the second semiconductor chip and the third wiring board.

13. The semiconductor device according to claim 8, wherein
the plurality of first bonding pads are aligned along two adjacent sides of the second wiring board,
the plurality of second bonding pads are aligned along two adjacent sides of the third wiring board, and
an arrangement of the two adjacent sides of the second wiring board is reversed with respect to the two adjacent sides of the third wiring board when viewed in a direction perpendicular to facing surfaces of the second semiconductor chip and the third wiring board.

14. The semiconductor device according to claim 13, wherein the plurality of first bonding pads are outside the second semiconductor device when viewed in a direction perpendicular to facing surfaces of the second semiconductor chip and the third wiring board.

15. The semiconductor device according to claim 8, wherein the third wiring board is inside the second semiconductor chip when viewed in a direction perpendicular to facing surfaces of the second semiconductor chip and the third wiring board.

16. The semiconductor device according to claim 8, wherein the second semiconductor chip is inside the third wiring board when viewed in a direction perpendicular to facing surfaces of the second semiconductor chip and the third wiring board.

17. The semiconductor device according to claim 8, further comprising
a seal covering the first region and the first and second semiconductor devices.

18. A semiconductor device comprising:
a semiconductor chip;
a plurality of electrode pads on the semiconductor chip, the plurality of electrode pads being in a center region of the semiconductor chip;
a wiring board fixed to the semiconductor chip;
a plurality of connection pads on the wiring board, the plurality of second connection pads facing the plurality of electrode pads;
a plurality of bonding pads aligned along two sides of the wiring board; and
a plurality of leads on the wiring board, the plurality of leads connecting the plurality of connection pads to the plurality of bonding pads.

19. The semiconductor device according to claim 18, wherein the plurality of bonding pads are aligned along two opposing sides of the wiring board.

20. The semiconductor device according to claim 1, wherein the plurality of bonding pads are aligned along two adjacent sides of the wiring board.
